(19) United States
(12) Patent Application Publication
(10) Pub. No.: US 2012/0103682 A1
(43) Pub. Date: May 3, 2012

(54) LEAD FRAME HAVING METAL CUP WITH ENLARGED HEAT-DISSPIATION AREA

(75) Inventors: YEN-CHIH CHANG, New Taipei (TW); CHIH-PI CHENG, New Taipei (TW)

(73) Assignee: HON HAI PRECISION INDUSTRY CO., LTD., New Taipei (TW)

(21) Appl. No.: 13/241,288

(22) Filed: Sep. 23, 2011

(30) Foreign Application Priority Data
Nov. 2, 2010 (TW) 099137636

(51) Int. Cl. H01L 23/495; H05K 1/18

(52) U.S. Cl. 174/529; 174/260

(57) ABSTRACT

A lead frame includes an insulative housing defining a cavity, a plurality of leads mounted with the housing and a metal cup mounted within the housing. Each lead includes contacting section exposed in the cavity. The metal cup includes a bottom plate and an inclined cup wall. The bottom plate is formed with a flange extending outwardly therefrom such that a slot is defined between the flange and the cup wall to receive the resin material of the housing.

### BACKGROUND OF THE INVENTION

1. Field of the Invention

The present invention relates to a lead frame for receiving an LED chip, and particularly to a lead frame having a metal cup incorporated with an enlarged bottom surface for heat dissipation.

2. Description of Related Art

U.S. Pat. No. 6,459,130 issued to Arndt et al. on Oct. 1, 2002 discloses an LED lead frame which includes a housing and a pair conductive leads mounted with the housing. An LED chip is received in a space defined by the housing and electrically connected to the leads. The lead has a mounting section extending to a bottom surface of the housing and engaged with a printed circuit board (PCB).

However, the LED lead frame according to Arndt is not readily arranged for dissipating heat generated by the LED chip as it is to be dissipated via the conductive leads, and the translucent material used to make the housing is thus likely to become darker over a period of time of usage and is not good for light reflection.

In view of the above, an improved lead frame is desired to overcome the problems mentioned above.

### SUMMARY OF THE INVENTION

Accordingly, an object of the present invention is to provide a lead frame with a metal cup which has incorporated with a large heat dissipation area.

According to one aspect of the present invention, there is provided a lead frame which includes an insulative housing defining a cavity, a plurality of leads mounted with the housing and a metal cup mounted within the housing. Each lead includes contacting section exposed in the cavity. The metal cup includes a bottom plate and an inclined cup wall. The bottom plate is formed with a flange extending outwardly therefrom such that a slot is defined between the flange and the cup wall to receive the resin material of the housing.

Other objects, advantages and novel features of the invention will become more apparent from the following detailed description when taken in conjunction with the accompanying drawings, in which:

### BRIEF DESCRIPTION OF THE DRAWINGS

FIG. 1 is an assembled, perspective view of a lead frame in accordance with a preferred embodiment of the present invention;

FIG. 2 is another assembled, perspective view of the lead frame as shown in FIG. 1.

FIG. 3 is an exploded, perspective view of the lead frame as shown in FIG. 1;

FIG. 4 is another exploded, perspective view of the lead frame as shown in FIG. 3.

FIG. 5 is a side view of a metal cup and leads of the lead frame in accordance with the preferred embodiment of the present invention; and

FIG. 6 is a sectional view of the lead frame, taken from a line 6-6 in FIG. 1.

### DETAILED DESCRIPTION OF THE INVENTION

Reference will now be made to the drawings to describe the present invention in detail.

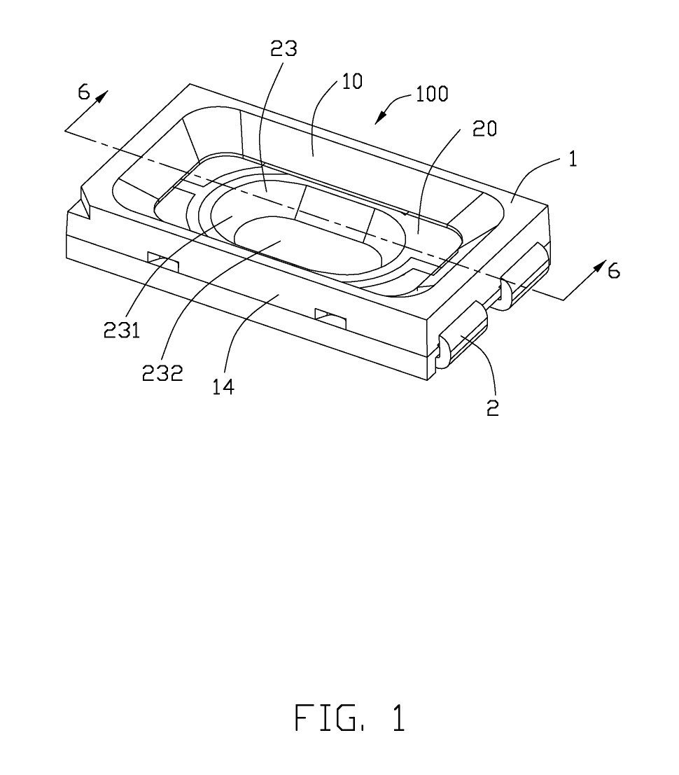

Referring to FIG. 1 to FIG. 4, a lead frame 100 for connecting an LED chip (not shown) is made in accordance with a preferred embodiment of the present invention. The lead frame 100 includes an insulative housing 1 and a plurality of leads 2 mounted with the housing 1. The lead 2 serves not only as a mounting member for mounting the lead frame 100 onto a PCB (not shown), but also as a conductive member for electrical connection between the LED chip and the PCB.

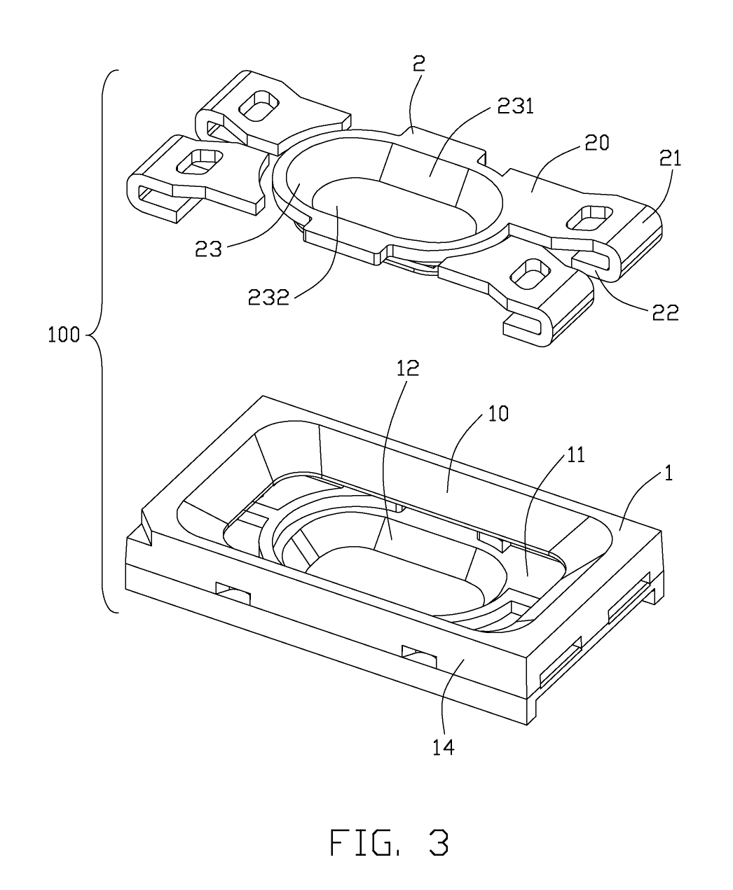

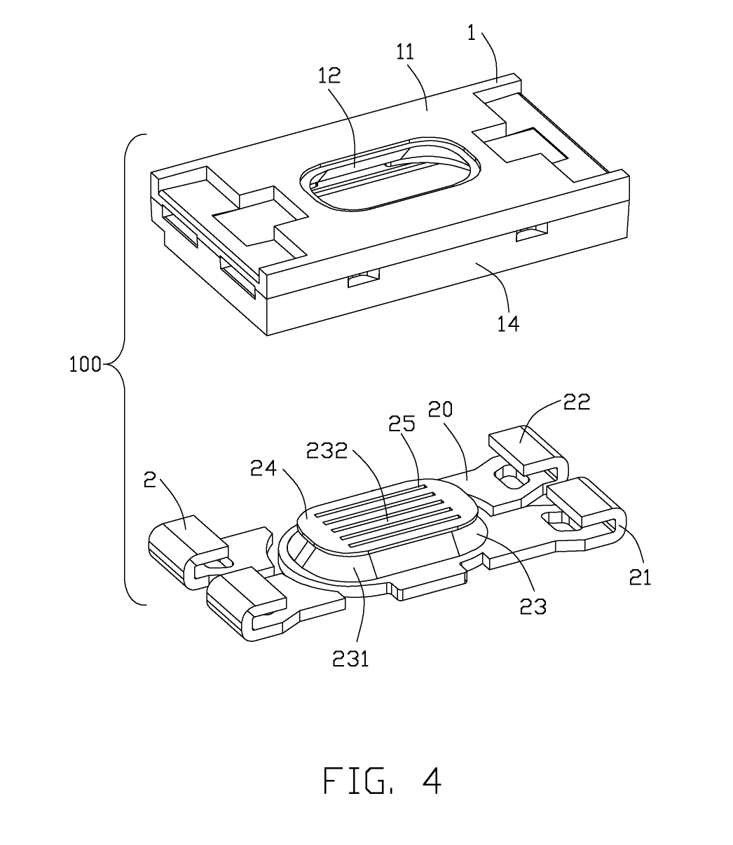

Particularly referring to FIG. 3 and FIG. 4, the housing 1 is formed with a substantially rectangular shape, and is molded with the leads 2 by injection process. The housing 1 includes a side wall 14 located at periphery position and defining a cavity therebetween. Under the cavity 10 there is a planner step portion 11. A receiving space 12 is formed and recessed downwardly from the step portion 11 and communicated with the cavity 10.

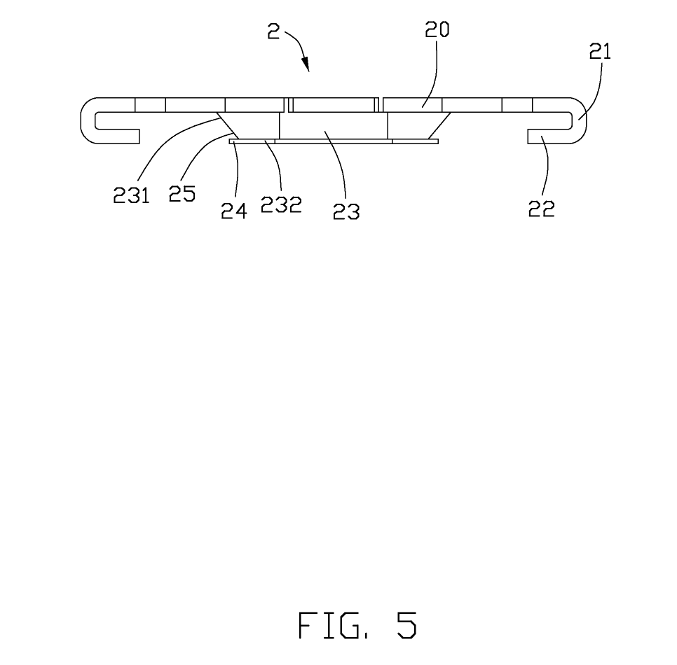

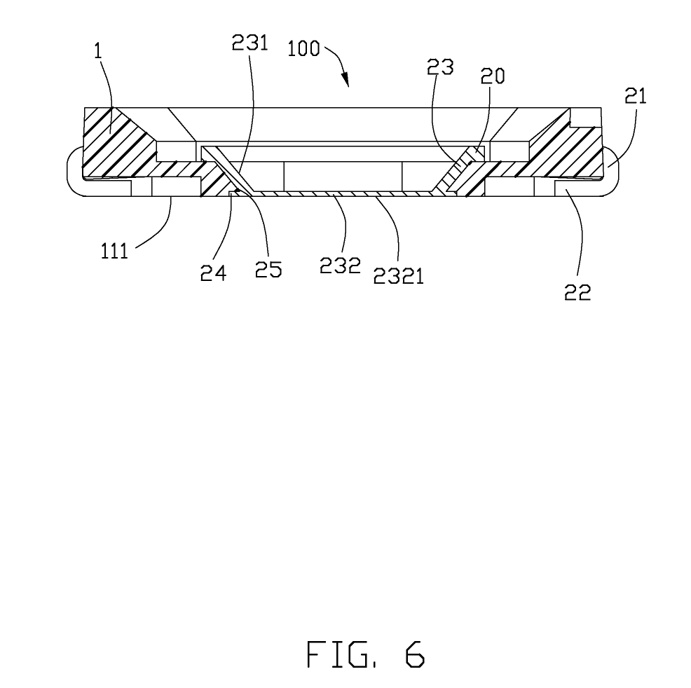

Particularly referring to FIG. 5 to FIG. 6, the lead 2 is made by stamping a metal plate, such as copper. Each lead 2 is partially embedded in the housing 1 and includes a connecting portion 20 exposed in the cavity 10, a mounting section 22 located at the bottom of the housing 1 and engaged with the PCB, and a bending section 21 interconnecting the contacting section 20 and the mounting section 22. A metal cup 23 is formed by integrally extending from one of the leads 2. The metal cup 23 is located in the receiving space 12 and includes an inclined cup wall 231 and a bottom plate 232. The LED chip is secured on the bottom plate 232 of the metal cup 23 and is preferably electrically and physically connected with the metal cup 23 and another lead 2 by a conductive wire, such as a golden wire (not shown). The bottom plate 232 is formed with a flange 24 extending outwardly therefrom such that a slot 25 is defined between the flange 24 and the cup wall 231 to receive the resin material of the housing 1. The flange 24 engages the hosing 1 directly and is able to increase the retention force between the metal cup 23 and the housing 1, and prevent upward movement of the metal cup 23 relative to the housing 1. In addition, the flange 24 is also able to enlarge the area of the bottom plate 232 for heat dissipation.

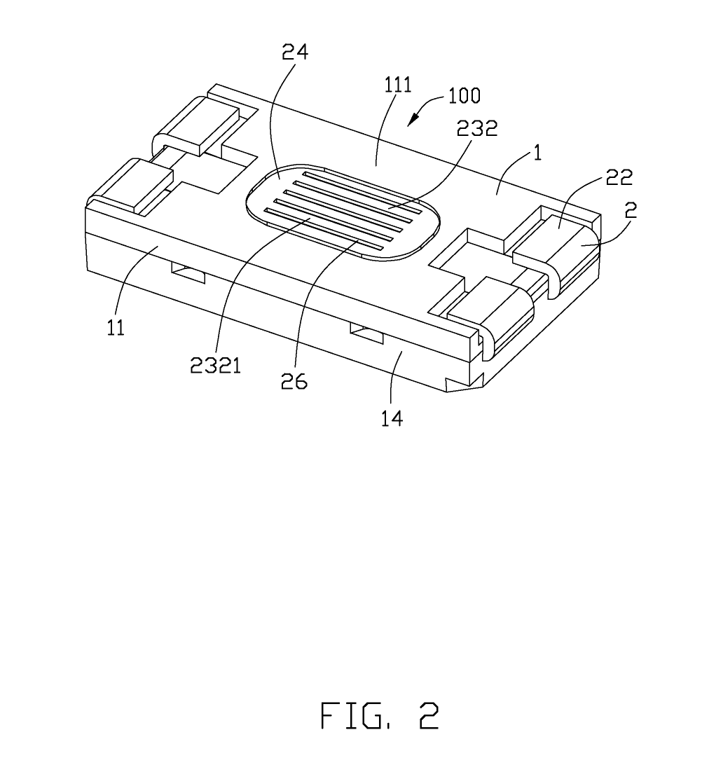

The bottom plate 232 of the metal cup 23 has a bottom surface 2321 coplanar with a bottom surface 111 of the housing 1, and the mounting section 22 of the lead 2 is also substantially coplanar with the bottom plate 232 of the metal cup 23. Referring to FIG. 2, the bottom surface 2321 of the metal cup 23 is provided with a plurality of grooves 26 so as to further expand the area for heat dissipation.

While preferred embodiments in accordance with the present invention has been shown and described, equivalent modifications and changes known to persons skilled in the art according to the spirit of the present invention are considered within the scope of the present invention as defined in the appended claims.

What is claimed is:

1. A lead frame, comprising:
an insulative housing defining a cavity;
a plurality of leads mounted with the housing and each comprising a contacting section exposed in the cavity; and
a metal cup mounted within the housing and comprising a bottom plate and an inclined cup wall, the bottom plate being formed with a flange extending outwardly therefrom such that a slot is defined between the flange and the cup wall to receive the resin material of the housing.

2. The lead frame as claimed in claim 1, wherein the metal cup is integrally extended from one of the leads.

3. The lead frame as claimed in claim 1, wherein the bottom plate of the metal cup has a bottom surface which is substantially coplanar with a bottom surface of the housing.

4. The lead frame as claimed in claim 3, wherein the bottom surface of the bottom plate is provided with a plurality of grooves so as to expand the area for heat dissipation.

5. The lead frame as claimed in claim 1, wherein the lead comprises a mounting section which is substantially coplanar with the bottom plate of the metal cup.

6. A lead frame mounted on a PCB for receiving an LED chip, comprising:
an insulative housing defining a cavity;
a metal cup mounted within the housing and receiving the LED chip therein, the metal cup comprising a bottom plate formed with a flange extending outwardly and directly engaged with the hosing to prevent upward movement of the metal cup relative to the housing; and
a plurality of leads mounted with the housing and each comprising a contacting section exposed in the cavity for electrical connection with the LED chip and a mounting section extend to the bottom of the housing and engaged with the PCB.

7. The lead frame as claimed in claim 6, wherein the metal cup further comprises an inclined cup wall, the cup wall and the flange jointly defining a slot therebetween for receiving the resin material of the housing.

8. The lead frame as claimed in claim 6, wherein the bottom plate of the metal cup has a bottom surface which is substantially coplanar with a bottom surface of the housing.

9. The lead frame as claimed in claim 8, wherein the bottom surface of the bottom plate is provided with a plurality of grooves so as to expand the area for heat dissipation.

10. The lead frame as claimed in claim 6, wherein the mounting section of the lead is substantially coplanar with the bottom plate of the metal cup.

11. A lead frame for use with a LED chip, comprising:
a metallic cup having an inclined wall with a bottom wall; and
a peripheral flange formed on junction between the inclined wall and bottom wall.

12. The lead frame as recited in claim 11, wherein a bottom surface of the bottom wall is defined with a plurality of slots.

13. The lead frame as recited in claim 11, wherein the flange essentially extends coplanar with the bottom wall horizontally.

14. The lead frame as recited in claim 13, wherein a loop type slot is formed between the inclined wall and the flange.

15. The lead frame as recited in claim 11, wherein said inclined wall extends in a complete loop.

16. The lead frame as recited in claim 11, further including an insulative housing integrally formed with the metallic cup.

17. The lead frame as recited in claim 16, wherein the housing defines a bottom face coplanar with the bottom surface of the bottom wall.

18. The lead frame as recited in claim 11, wherein the flange extends horizontally and outwardly away from the bottom wall.
